(19) United States
(12) Patent Application Publication
(10) Pub. No.: US 2023/0141911 A1
(43) Pub. Date: May 11, 2023

(54) SUBSTRATE PROCESSING SYSTEM

(71) Applicant: Tokyo Electron Limited, Tokyo (JP)

(72) Inventor: Dai KITAGAWA, Miyagi (JP)

(73) Assignee: Tokyo Electron Limited, Tokyo (JP)

(21) Appl. No.: 17/950,116

(22) Filed: Sep. 22, 2022

(30) Foreign Application Priority Data
Nov. 9, 2021 (JP) 2021-182487

(51) Int. Cl. H01J 37/32

(52) U.S. Cl. CPC H01J 37/32899; H01J 37/32743; H01J 37/32715; H01J 37/32816; H01J 2237/20278; H01J 2237/20235; H01J 2237/186

(57) ABSTRACT

A substrate processing system is installable in a small installation area. The substrate processing system includes one or more process modules and a vacuum transfer module. At least one of the one or more process modules and the vacuum transfer module at least partially overlap with each other as viewed from above.

### CROSS-REFERENCE TO RELATED APPLICATION

This application claims priority to Japanese Patent Application No. 2021-182487 filed on Nov. 9, 2021, the entire contents of which is incorporated herein by reference.

### BACKGROUND

### Technical Field

Various aspects and embodiments of the present disclosure relate to a substrate processing system.

### Description of the Background

Patent Literature 1 explains that “each processing tool 200 includes an improved equipment front end module (EFEM) 204 to accommodate at least a part of a loadlock 208”. Patent Literature 1 further explains that the loadlock 208 extends in the EFEM 204, instead of being positioned outside the EFEM 204 in the space between the EFEM 204 and a vacuum transfer module (VTM) 212.

### CITATION LIST

### Patent Literature

Patent Literature 1: Japanese Unexamined Patent Application Publication No. 2020-510310

### BRIEF SUMMARY

One or more aspects of the present disclosure are directed to a substrate processing system installable in a small installation area.

A substrate processing system according to one aspect of the present disclosure includes one or more process modules and a vacuum transfer module. At least one of the one or more process modules and the vacuum transfer module at least partially overlap with each other as viewed from above.

The substrate processing system according to various aspects and embodiments of the present disclosure is installable in a small installation area, as compared with conventional systems.

### BRIEF DESCRIPTION OF DRAWINGS

FIG. 1 is a plan view of an exemplary substrate processing system according to one embodiment.

FIG. 2 is a side view of the exemplary substrate processing system as viewed in the direction indicated by arrow C in FIG. 1.

FIG. 3 is a side view of the exemplary substrate processing system as viewed in the direction indicated by arrow D in FIG. 1.

FIG. 4 is a side view of the exemplary substrate processing system as viewed in the direction indicated by arrow E in FIG. 1.

FIG. 5 is a diagram of the substrate processing system in FIG. 1 showing its exemplary back surface.

FIG. 6 is a schematic cross-sectional view of the substrate processing system illustrated in FIGS. 1 and 5, showing its exemplary cross section taken along line A-A.

FIG. 7 is a schematic cross-sectional view of the substrate processing system illustrated in FIGS. 1 and 5, showing its exemplary cross section taken along line B-B.

FIG. 8 is a schematic cross-sectional view of an exemplary process module (PM).

FIG. 9 is a diagram describing an example system (or structure) in a particular state during a process for transferring a substrate.

FIG. 10 is a diagram describing the example system in a particular state during a process for transferring the substrate.

FIG. 11 is a diagram describing an example support used in transferring and receiving the substrate.

FIG. 12 is a diagram describing the example system in a particular state during a process for transferring the substrate.

FIG. 13 is a diagram describing an example support used for transferring and receiving the substrate.

FIG. 14 is a diagram describing an exemplary positional relationship between a substrate support and an arm.

FIG. 15 is a diagram describing the example system in a particular state during a process for transferring the substrate.

FIG. 16 is a diagram describing an example support used for transferring and receiving the substrate.

FIG. 17 is a diagram describing the example system in a particular state during a process for transferring the substrate.

FIG. 18 is a diagram describing the example system in a particular state during a process for transferring the substrate.

FIG. 19 is a diagram describing an example support used for transferring and receiving the substrate.

FIG. 20 is a diagram describing the example system in a particular state during a process for transferring the substrate.

FIG. 21 is a diagram describing the example system in a particular state during a process for transferring the substrate.

FIG. 22 is a diagram describing the example system in a particular state during a process for transferring the substrate.

FIG. 23 is a schematic cross-sectional view of a substrate processing system in another example.

FIG. 24 is a schematic cross-sectional view of a substrate processing system in another example.

FIG. 25 is a schematic cross-sectional view of a substrate processing system in another example.

FIG. 26 is a schematic cross-sectional view of a substrate processing system in another example.

FIG. 27 is a schematic cross-sectional view of a substrate processing system in another example.

FIG. 28 is a schematic cross-sectional view of a substrate processing system in another example.

### DETAILED DESCRIPTION

A substrate processing system according to one or more embodiments will be described with reference to the drawings. The substrate processing system according to one or more embodiments of the disclosure is not limited to the embodiments described below.

To process more substrates per unit time, a substrate processing system may include an increased number of processing modules for processing substrates. An increased number of processing modules can increase the size of a substrate processing system that includes, for example, multiple processing modules, a vacuum transfer module, a loadlock module, and an atmospheric transfer module. A substrate processing system with an increased size uses a larger installation area (footprint) in, for example, a clean room at a facility, thus causing difficulty in arranging multiple substrate processing systems. Substrate processing systems that use smaller installation areas are thus awaited.

A substrate processing system according to one or more embodiments of the present disclosure is installable in a smaller installation area.

### Structure of Substrate Processing System 10

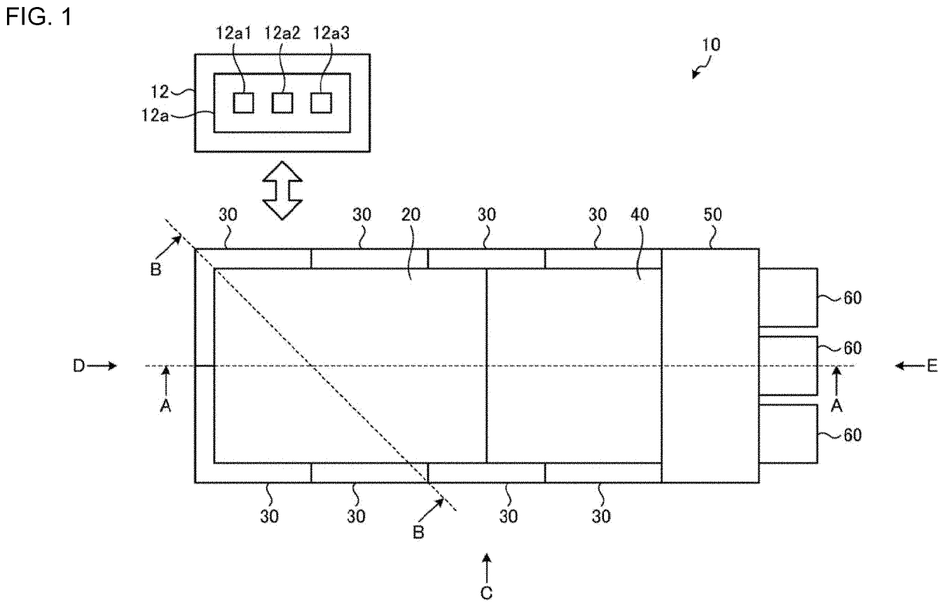

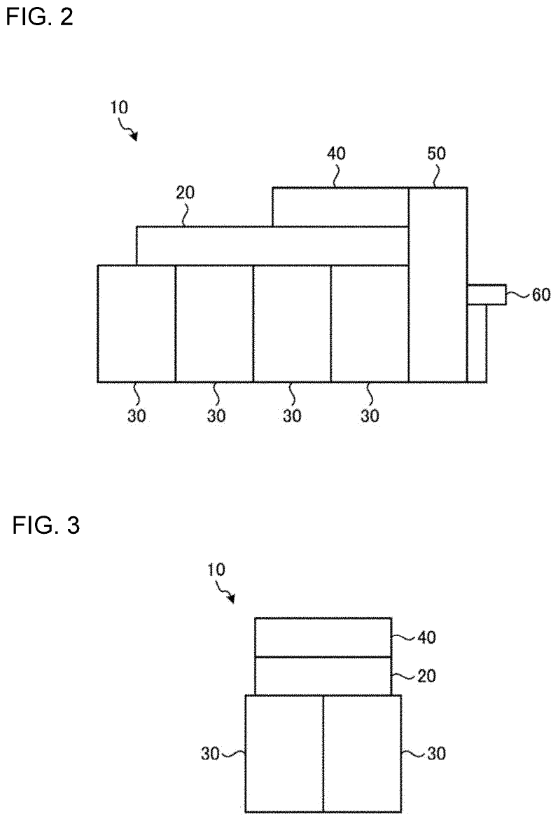

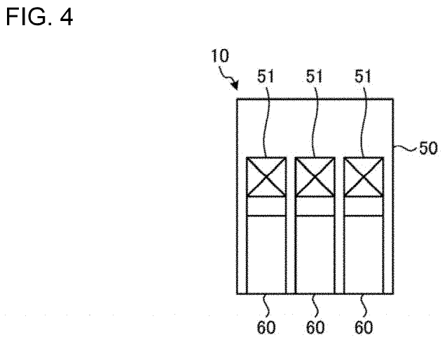

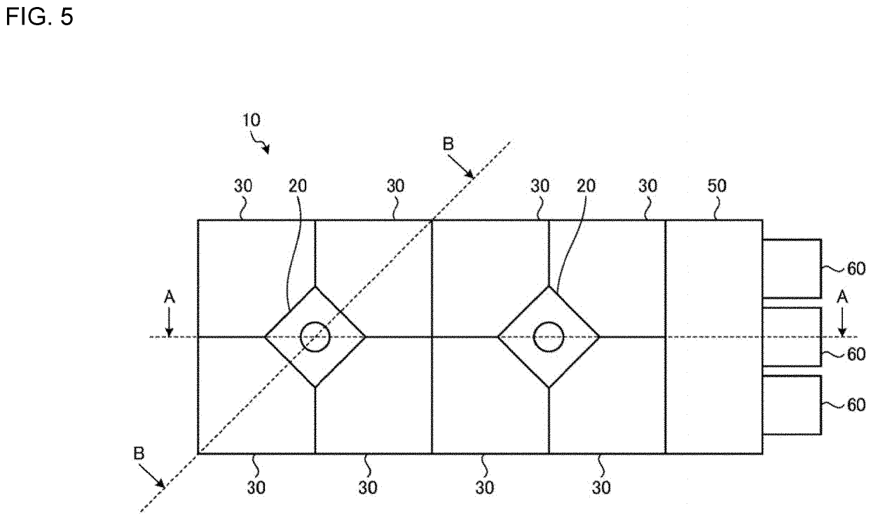

FIG. 1 is a plan view of an exemplary substrate processing system 10 according to one embodiment. FIG. 2 is a side view of the exemplary substrate processing system 10 as viewed in the direction indicated by arrow C in FIG. 1. FIG. 3 is a side view of the exemplary substrate processing system 10 as viewed in the direction indicated by arrow D in FIG. 1. FIG. 4 is a side view of the exemplary substrate processing system 10 as viewed in the direction indicated by arrow E in FIG. 1. FIG. 5 is a diagram of the substrate processing system 10 in FIG. 1 showing its exemplary back surface. FIG. 1 illustrates, together with the substrate processing system 10, a control device 12 (also referred to as a “controller”) that controls the entire substrate processing system 10.

The substrate processing system 10 includes a vacuum transfer module (VTM) 20, multiple process modules (PMs) 30, a loadlock module (LLM) 40, an equipment front end module (EFEM) 50, and multiple load ports (LPs) 60.

The VTM 20 transfers a substrate W in a vacuum atmosphere. The term vacuum herein refers to a pressure lower than atmospheric pressure. The VTM 20 transfers the substrate W between the PM 30 and the LLM 40 or between multiple PMs 30 in a vacuum atmosphere. In the present embodiment, at least one PM 30 and the VTM 20 overlap with each other at least partially as viewed from above. In the present embodiment, being viewed from “above” refers to viewing an upper surface in the vertical direction. Similarly, one object being “over” another object refers to a first object that is positioned to at least partially overlap a second object that underlies the first object such that a complete view of an upper surface of the second object is blocked by the presence of the first object as viewed from above. Likewise, “under” in this context refers to the position of the second object with respect to the first object. As with “above”, neither “over” nor “under” required a complete overlapping of the first object's footprint with respect to the second object's footprint. In the example of FIGS. 1 to 5, the VTM 20 is located on at least one PM 30 as viewed from above. Although the substrate processing system 10 includes one VTM 20 in the example of FIGS. 1 to 5, the techniques described according to the present disclosure are not limited to this particular configuration. The substrate processing system 10 may include more than one VTM 20.

Each PM 30 performs processing (e.g., plasma processing) on a substrate W, including etching and film deposition. Each PM 30 may perform the same step or a different step of the manufacturing steps. Although the substrate processing system 10 includes eight PMs 30 in the example of FIGS. 1 to 5, the techniques described according to the present disclosure are not limited to this particular configuration. The substrate processing system 10 may include fewer or more than eight PMs 30.

Although each PM 30 appears square as viewed from above in the example of FIGS. 1 to 5, the techniques described according to the present disclosure are not limited to this particular configuration. Each PM 30 may be, for example, polygonal, circular, or elliptic as viewed from above. A polygonal PM 30 may be triangular, quadrilateral (e.g., rectangular, rhombic, or trapezoidal), pentagonal, hexagonal, or octagonal as viewed from above.

The LLM 40 controllably switches an internal pressure between a vacuum atmosphere and an ambient atmosphere. The LLM 40 and at least one PM 30 overlap with each other at least partially as viewed from above. In the present embodiment, at least a part of the VTM 20 is located between at least one PM 30 and the LLM 40. In the present embodiment, the VTM 20, at least one PM 30, and the LLM 40 overlap with one another at least partially as viewed from above. In the example of FIGS. 1 to 5, the LLM 40 is located on the VTM 20. Although the substrate processing system 10 includes one LLM 40 in the example of FIGS. 1 to 5, the techniques described according to the present disclosure are not limited to this particular configuration. The substrate processing system 10 may include more than one LLM 40.

The EFEM 50 transfers the substrate W in an ambient atmosphere. The EFEM 50 is an example of an atmospheric transfer module. The EFEM 50 has a side wall with multiple LPs 60. The EFEM 50 includes, on its side wall, gate valves 51 corresponding to the respective LPs 60 as shown in, for example, FIG. 4. The EFEM 50 transfers the substrate W between a front opening unified pod (FOUP) installed in the corresponding LP 60 and the LLM 40 in an ambient atmosphere. Although the substrate processing system 10 includes one EFEM 50 in the example of FIGS. 1 to 5, the techniques described according to the present disclosure are not limited to this particular configuration. The substrate processing system 10 may include more than one EFEM 50. Although the substrate processing system 10 includes three LPs 60 in the example of FIGS. 1 to 5, the techniques described according to the present disclosure are not limited to this particular configuration. The substrate processing system 10 may include fewer or more than three LPs 60.

The substrate processing system 10 may include an alignment module that adjusts the position and orientation of the substrate W. The alignment module may be included in any of the components, but may be included in, for example, the VTM 20, the EFEM 50, or the LLM 40.

The control device 12 processes computer-executable instructions that cause the substrate processing system 10 to perform various steps described in the present disclosure. The control device 12 may control the components of the substrate processing system 10 to perform various steps described herein. In one embodiment, some or all of the components of the control device 12 may be included in the substrate processing system 10. The control device 12 is implemented by, for example, a computer 12a including a processor 12a1, a storage device (e.g., a computer readable memory) 12a2, and a communication interface 12a3. The processor 12a1 performs various control operations by reading a program from the storage device 12a2 and executing instructions contained in the program. This program may be prestored in the storage device 12a2 or may be obtained through a medium as appropriate. The obtained program is stored into the storage device 12a2, read from the storage device 12a2, and executed by the processor 12a1. The medium may be one of various storage media readable by the computer 12a, or a communication line connected to the communication interface 12a3 that provides program instructions from a remote source. The processor 12a1 may be one or more central processing unit(s) (CPUs), graphical processing unit(s) (GPUs), and/or hybrid processors with programmable devices and programmed/programmable devices (e.g., application specific integrated circuits (ASICs), programmable logic devices (PLDs) and the like). The processor 12a1, as well as other processors described herein, need not be a signal processor, but can be more or more processors located adjacent to one another, or separated by some distance and connected by way of the communication line, or a different communication line. For example, the processor 12a1 may include a local processor and/or cloud processing resources implemented in one or more remote locations. The storage device 12a2 may be a random-access memory (RAM), a read-only memory (ROM), a hard disk drive (HDD), a solid-state drive (SSD), or a combination of these memories. The communication interface 12a3 may communicate with the substrate processing system 10 through a communication line such as the physical layer (e.g., Ethernet) of a local area network (LAN). Also, “communication line” in this context may be a wireless communication link that conveys digital information via wireless transmissions such as 5G, WiFi, or the like. The communication interface 12a3 may also include a dedicated interface, such as a display panel and/or touch-panel for displaying status information and allowing for control input.

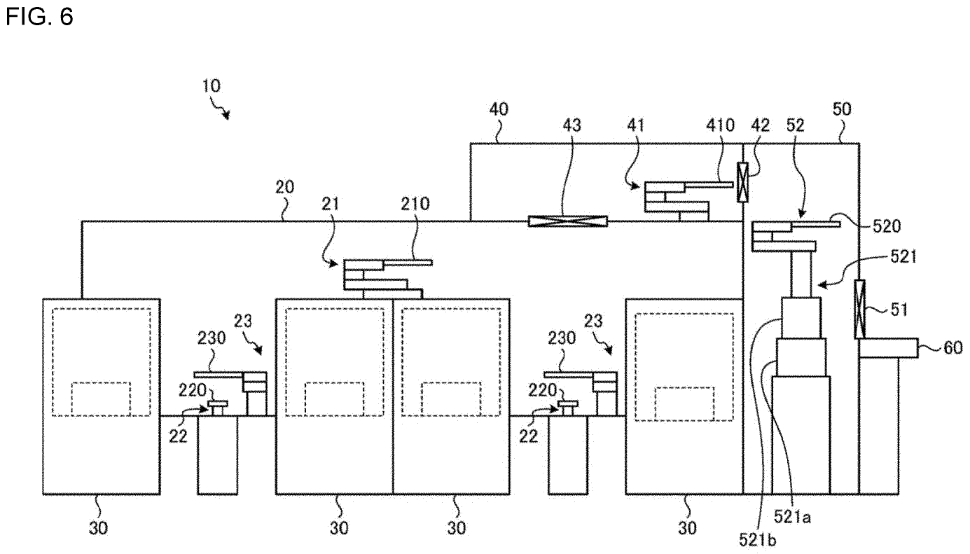

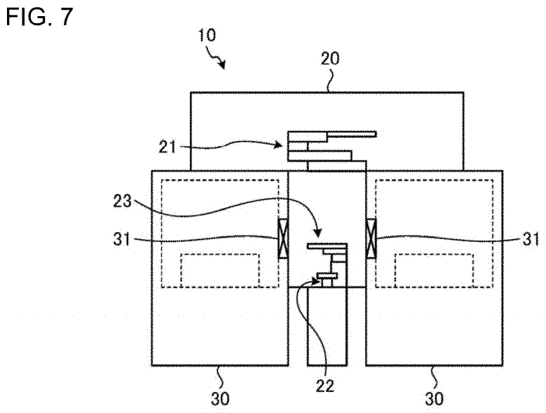

FIG. 6 is a schematic cross-sectional view of the substrate processing system 10 illustrated in FIGS. 1 and 5, showing its exemplary cross section taken along line A-A. FIG. 7 is a schematic cross-sectional view of the substrate processing system 10 illustrated in FIGS. 1 and 5, showing its exemplary cross section taken along line B-B.

A transfer robot 52 is located in the EFEM 50. The transfer robot 52 transfers the substrate W between the FOUP installed in the corresponding LP 60 and the LLM 40. The transfer robot 52 can move within the EFEM 50, for example, in the direction along arrow C in FIG. 1. The transfer robot 52 includes a substrate support 520 on which the substrate W is placeable, and an arm 521 that moves the substrate support 520. The arm 521 includes a cylinder 521a and a cylinder 521b. The cylinder 521a is located in the EFEM 50 to have the axis in the vertical direction. The cylinder 521b is placeable in the cylinder 521a. The cylinder 521b in the EFEM 50 is coaxial with the cylinder 521a. The arm 521 is extendable in the vertical direction along the axis of the cylinder 521a to move the substrate support 520 in the vertical direction by sliding the cylinder 521b relative to the cylinder 521a. This structure reduces the installation area of the transfer robot 52.

A gate valve 42 is located between the EFEM 50 and the LLM 40. A gate valve 43 is located between the LLM 40 and the VTM 20. A transfer robot 41 is located in the LLM 40. The transfer robot 41 includes a substrate support 410 on which the substrate W is placeable.

A transfer robot 21 is located above the PM 30 in the VTM 20. The transfer robot 21 includes a substrate support 210 on which the substrate W is placeable. A transfer robot 22 and a transfer robot 23 are located between adjacent PMs 30 in the VTM 20. The transfer robot 22 includes a substrate support 220 on which the substrate W is placeable. The transfer robot 23 includes a substrate support 230 on which the substrate W is placeable. A gate valve 31 is located between the VTM 20 and the PM 30 as shown in, for example, FIG. 7.

### Structure of PM 30

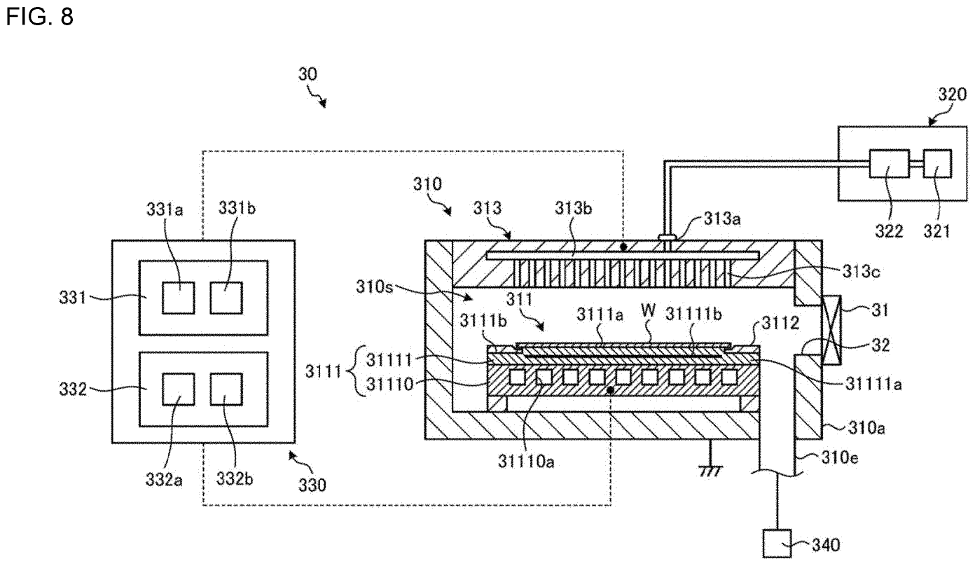

FIG. 8 is a schematic cross-sectional view of an exemplary PM 30. In the present embodiment, the PM 30 is, for example, a capacitively coupled plasma (CCP) processing apparatus. The PM 30 includes a plasma processing chamber 310, a gas supply unit 320, a power supply 330, and an exhaust system 340. The PM 30 also includes a substrate support 311 and a gas inlet unit. The gas inlet unit allows at least one process gas to be introduced into the plasma processing chamber 310. The gas inlet unit includes a shower head electrode 313. The substrate support 311 is located in the plasma processing chamber 310. The shower head electrode 313 is located above the substrate support 311. In one embodiment, the shower head electrode 313 defines at least a part of the ceiling of the plasma processing chamber 310. The plasma processing chamber 310 has a plasma processing space 310s defined by the shower head electrode 313, a side wall 310a of the plasma processing chamber 310, and the substrate support 311. The plasma processing chamber 310 has at least one gas inlet for supplying at least one process gas into the plasma processing space 310s and at least one gas outlet for discharging the gas from the plasma processing space 310s. The plasma processing chamber 310 is grounded. The shower head electrode 313 and the substrate support 311 are electrically insulated from the housing of the plasma processing chamber 310. The side wall 310a of the plasma processing chamber 310 has an opening 32 for loading and unloading the substrate W. The opening 32 is opened and closed by the gate valve 31.

The substrate support 311 includes a body 3111 and a ring assembly 3112. The body 3111 includes a central area 3111a for supporting the substrate W and an annular area 3111b for supporting the ring assembly 3112. A wafer is an example of the substrate W. The annular area 3111b of the body 3111 surrounds the central area 3111a of the body 3111 as viewed in plan. The substrate W is located on the central area 3111a of the body 3111. The ring assembly 3112 is located on the annular area 3111b of the body 3111 to surround the substrate W on the central area 3111a of the body 3111. The central area 3111a is also referred to as a substrate support surface for supporting the substrate W. The annular area 3111b is also referred to as a ring support surface for supporting the ring assembly 3112.

In one embodiment, the body 3111 includes a base 31110 and an electrostatic chuck (ESC) 31111. The base 31110 includes a conductive member. The conductive member in the base 31110 may function as a lower electrode. The ESC 31111 is located on the base 31110. The ESC 31111 includes a ceramic member 31111a and an electrostatic electrode 31111b located inside the ceramic member 31111a. The ceramic member 31111a includes a central area 3111a. In one embodiment, the ceramic member 31111a also includes an annular area 3111b. Other members surrounding the ESC 31111, such as an annular ESC or an annular insulating member, may include the annular area 3111b. In this case, the ring assembly 3112 may be located on the annular ESC or the annular insulating member, or may be located on both the ESC 31111 and the annular insulating member. At least one radio frequency (RF) electrode coupled to an RF power supply 331 or at least one direct current (DC) electrode coupled to a DC power supply 332, or both the RF electrode and the DC electrode (described later) may also be located inside the ceramic member 31111a. In this case, at least one RF electrode or at least one DC electrode, or both the electrodes serve as a lower electrode. When a bias RF signal or a DC signal or both (described later) are provided to at least one RF electrode or at least one DC electrode or to both the electrodes, the RF electrode or the DC electrode, or both the electrodes are also referred to as a bias electrode(s). The conductive member in the base 31110 and at least one RF electrode or at least one DC electrode, or both the electrodes may function as multiple lower electrodes. The electrostatic electrode 31111b may also function as a lower electrode. The substrate support 311 includes at least one lower electrode.

The ring assembly 3112 includes one or more annular members. In one embodiment, one or more annular members include one or more edge rings and at least one cover ring. The edge ring is formed from a conductive material or an insulating material. The cover ring is formed from an insulating material.

The substrate support 311 may also include a temperature control module that adjusts at least one of the ESC 31111, the ring assembly 3112, or the substrate W to a target temperature. The temperature control module may include a heater, a heat-transfer medium, a channel 31110a, or a combination of these. The channel 31110a allows a heat-transfer fluid such as brine or gas to flow. In one embodiment, the channel 31110a is defined in the base 31110, and one or more heaters are located in the ceramic member 31111a in the ESC 31111. The substrate support 311 may include a heat-transfer gas supply to supply a heat-transfer gas to the space between the back surface of the substrate W and the central area 3111a.

The shower head electrode 313 introduces at least one process gas from the gas supply unit 320 into the plasma processing space 310s. The shower head electrode 313 has at least one gas inlet 313a, at least one gas diffusing compartment 313b, and multiple gas inlet ports 313c. The process gas supplied to the gas inlet 313a passes through the gas diffusing compartment 313b and is introduced into the plasma processing space 310s through the multiple gas inlet ports 313c. The shower head electrode 313 also includes at least one upper electrode. In addition to the shower head electrode 313, the gas inlet unit may include one or more side gas injectors (SGIs) that are installed in one or more openings in the side wall 310a.

The gas supply unit 320 may include at least one gas source 321 and at least one flow controller 322. In one embodiment, the gas supply unit 320 allows supply of at least one process gas from each gas source 321 to the shower head electrode 313 through the corresponding flow controller 322. Each flow controller 322 may include, for example, a mass flow controller or a pressure-based flow controller. The gas supply unit 320 may further include one or more flow rate modulators that supply one or more process gases at a modulated flow rate or in a pulsed manner.

The power supply 330 includes an RF power supply 331 that is coupled to the plasma processing chamber 310 through at least one impedance matching circuit. The RF power supply 331 allows supply of at least one RF signal (RF power) to at least one lower electrode or at least one upper electrode, or to both the electrodes. This causes plasma to be generated from one or more process gases supplied into the plasma processing space 310s. The RF power supply 331 may thus at least partially serve as a plasma generator that generates plasma from one or more process gases in the plasma processing chamber 310. A bias RF signal is provided to at least one of the lower electrodes to generate a bias potential in the substrate W, thus drawing ion components in the plasma to the substrate W.

In one embodiment, the RF power supply 331 includes a first RF generator 331a and a second RF generator 331b. The first RF generator 331a is coupled to at least one lower electrode or at least one upper electrode, or to both the electrodes through at least one impedance matching circuit and generates a source RF signal (source RF power) for plasma generation. In one embodiment, the RF signal has a frequency within the range of 10 to 150 MHz. In one embodiment, the first RF generator 331a may generate multiple source RF signals with different frequencies. The generated one or more source RF signals are provided to at least one lower electrode or at least one upper electrode, or to both the electrodes.

The second RF generator 331b is coupled to at least one lower electrode through at least one impedance matching circuit and generates a bias RF signal (bias RF power). The frequency of the bias RF signal may be the same as or different from the frequency of the source RF signal. In one embodiment, the bias RF signal has a lower frequency than the source RF signal. In one embodiment, the bias RF signal has a frequency within the range of 100 kHz to 60 MHz. In one embodiment, the second RF generator 331b may generate multiple bias RF signals with different frequencies. The generated one or more bias RF signals are provided to at least one lower electrode. In various embodiments, at least one of the source RF signal or the bias RF signal may be pulsed.

The power supply 330 may also include a DC power supply 332 coupled to the plasma processing chamber 310. The DC power supply 332 includes a first DC generator 332a and a second DC generator 332b. In one embodiment, the first DC generator 332a is connected to at least one lower electrode and generates a first DC signal. The generated first bias DC signal is applied to at least one lower electrode. In one embodiment, the second DC generator 332b is connected to at least one upper electrode and generates a second DC signal. The generated second DC signal is applied to at least one upper electrode.

In various embodiments, at least one of the first DC signal or the second DC signal may be pulsed. In this case, a sequence of voltage pulses is applied to at least one lower electrode or at least one upper electrode, or to both the electrodes. The voltage pulse may have a rectangular, trapezoidal, or triangular pulse waveform, or a combination of these pulse waveforms. In one embodiment, a waveform generator that generates a sequence of voltage pulses based on DC signals is connected between the first DC generator 332a and at least one lower electrode. Thus, the first DC generator 332a and the waveform generator are included in a voltage pulse generator. When the second DC generator 332b and the waveform generator are included in a voltage pulse generator, the voltage pulse generator is connected to at least one upper electrode. The voltage pulses may have positive or negative polarity. The sequence of voltage pulses may also include one or more positive voltage pulses and one or more negative voltage pulses within one cycle. The first DC generator 332a and the second DC generator 332b may be provided in addition to the RF power supply 331, or the first DC generator 332a may replace the second RF generator 331b.

The exhaust system 340 may be, for example, connected to a gas outlet 310e in the bottom of the plasma processing chamber 310. The exhaust system 340 may include a pressure control valve and a vacuum pump. The pressure in the plasma processing space 310s is regulated by the pressure control valve. The vacuum pump may include a turbomolecular pump, a dry pump, or a combination of these.

### Procedure for Transferring Substrate W

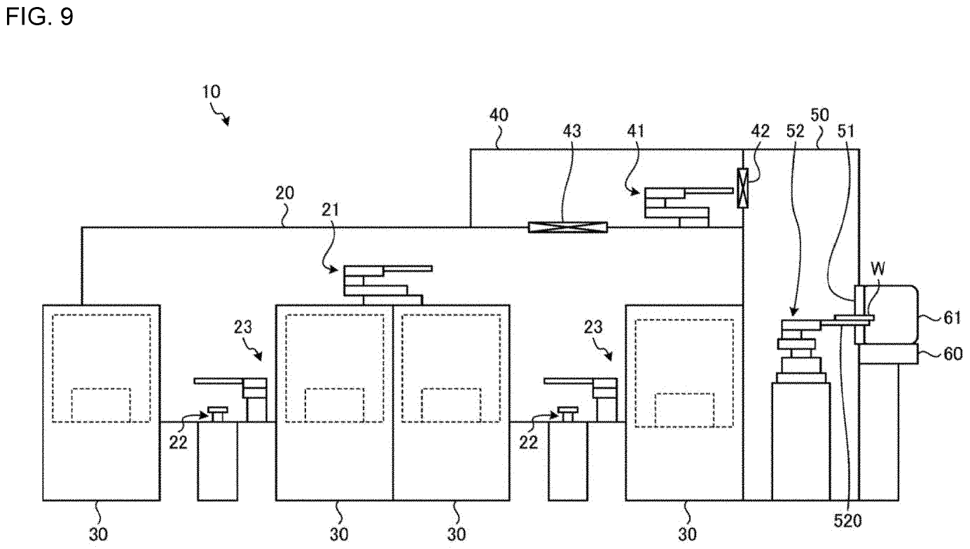

An example procedure for transferring a substrate W in the substrate processing system 10 will now be described with reference to FIGS. 9 to 22.

A FOUP 61 containing substrates W is first installed in the LP 60, and the gate valve 51 is opened. The substrate support 520 in the transfer robot 52 is placed into the FOUP 61, and a substrate W is placed on the substrate support 520. The substrate W is unloaded from the FOUP 61 as shown in, for example, FIG. 9.

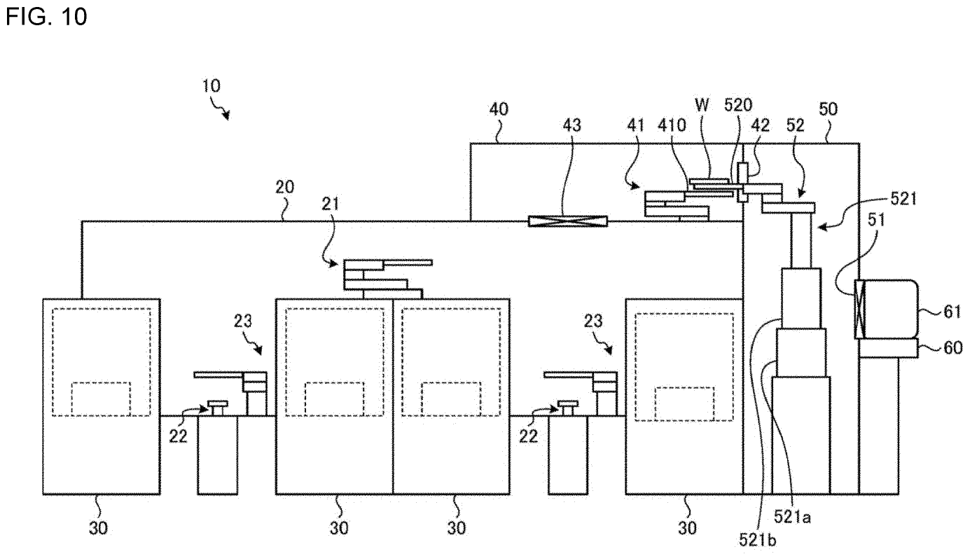

The arm 521 (FIG. 6) then extends to cause the substrate W on the substrate support 520 to be elevated to the position of the gate valve 42 as shown in, for example, FIG. 10. The gate valve 42 is then opened, with the LLM 40 being in an ambient atmosphere. As shown in FIG. 10, for example, the substrate support 520 receiving the substrate W is then placed into the LLM 40, and the substrate W is transferred from the substrate support 520 in the transfer robot 52 to the substrate support 410 in the transfer robot 41.

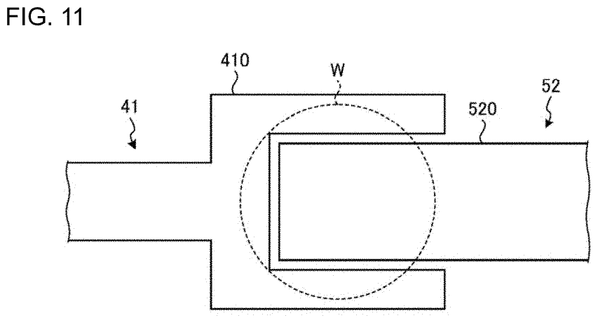

When the substrate W is transferred and received, the positional relationship between the substrate support 410 in the transfer robot 41 and the substrate support 520 in the transfer robot 52 is as shown in, for example, FIG. 11. FIG. 11 is a diagram describing an example process for transferring and receiving the substrate W. The substrate support 410 in the transfer robot 41 and the substrate support 520 in the transfer robot 52 can transfer and receive the substrate W between the two without interfering with each other.

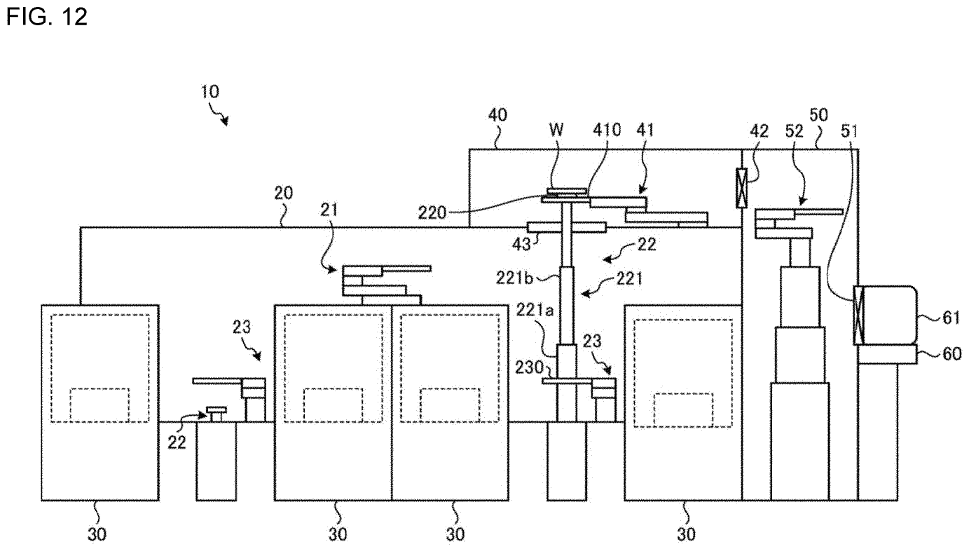

As shown in, for example, FIG. 12, the substrate support 520 in the transfer robot 52 is then retrieved from within the LLM 40, and the gate valve 42 is closed. The pressure in the LLM 40 is then decreased from an ambient atmosphere to a vacuum atmosphere. The substrate support 410 receiving the substrate W moves to above the gate valve 43, and the gate valve 43 is opened. As the transfer robot 22 below the gate valve 43 extends, the substrate support 220 in the transfer robot 22 is placed into the LLM 40 as shown in, for example, FIG. 12. The substrate support 220 in the transfer robot 22 then lifts the substrate W on the substrate support 410 in the transfer robot 41. The substrate support 410 in the transfer robot 41 is retrieved from above the gate valve 43. The substrate W is thus transferred from the substrate support 410 in the transfer robot 41 to the substrate support 220 in the transfer robot 22.

In the present embodiment, the transfer robot 22 includes the substrate support 220 on which the substrate W is placeable, and an arm 221 that moves the substrate support 220 in the vertical direction. The arm 221 includes a cylinder 221a and a cylinder 221b. The cylinder 221a is located in the VTM 20 to have the axis in the vertical direction. The cylinder 221b is placeable in the cylinder 221a. The cylinder 221b in the VTM 20 is coaxial with the cylinder 221a. The arm 221 is extendable in the vertical direction along the axis of the cylinder 221a to move the substrate support 220 in the vertical direction by sliding the cylinder 221b relative to the cylinder 221a. This structure reduces the installation area of the transfer robot 22. The cylinder 221a is an example of the first cylinder, and the cylinder 221b is an example of the second cylinder.

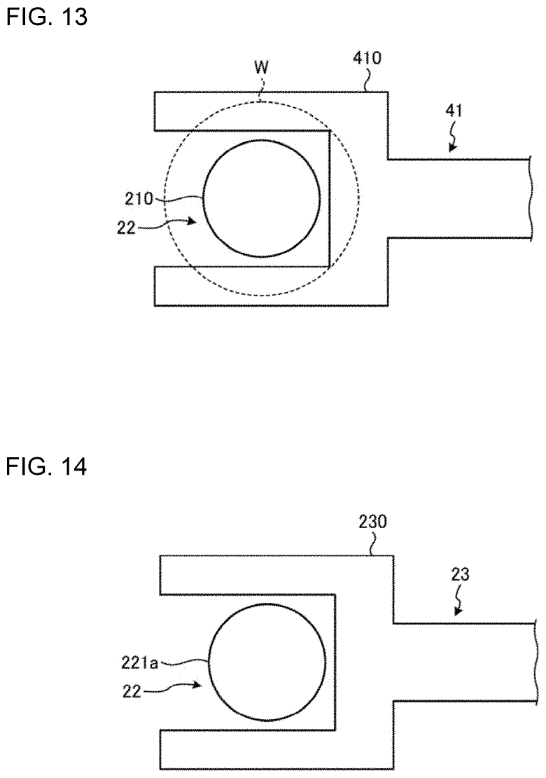

When the substrate W is transferred and received, the positional relationship between the substrate support 410 in the transfer robot 41 and the substrate support 220 in the transfer robot 22 is as shown in, for example, FIG. 13. FIG. 13 is a diagram describing an example process for transferring and receiving the substrate W. The substrate support 410 in the transfer robot 41 and the substrate support 220 in the transfer robot 22 can transfer and receive the substrate W between them without interfering with each other. When the substrate W is transferred from the substrate support 410 in the transfer robot 41 to the substrate support 220 in the transfer robot 22, the cylinder 221a in the arm 221 moves through a space between parts of the substrate support 230 in the transfer robot 23 as shown in, for example, FIG. 14. The cylinder 221a in the arm 221 thus does not interfere with the substrate support 230 in the transfer robot 23.

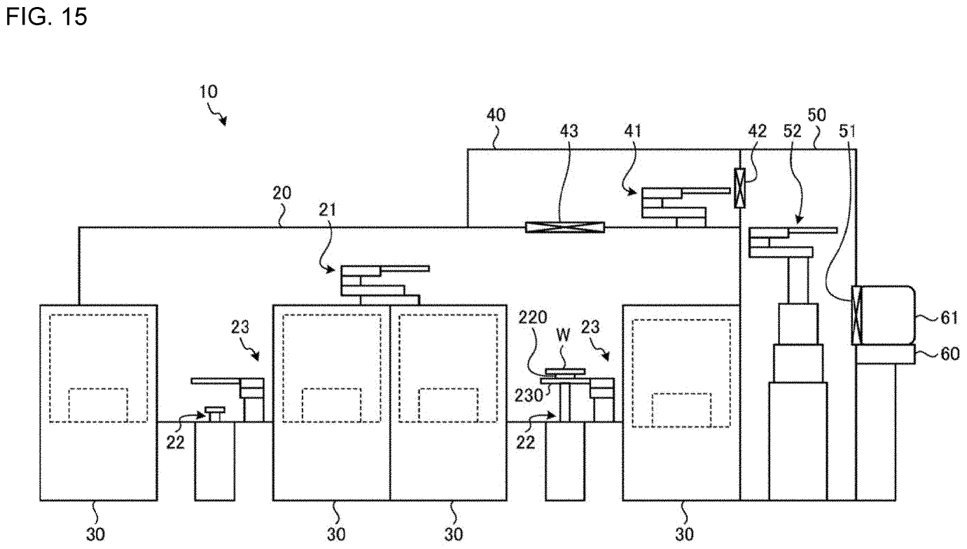

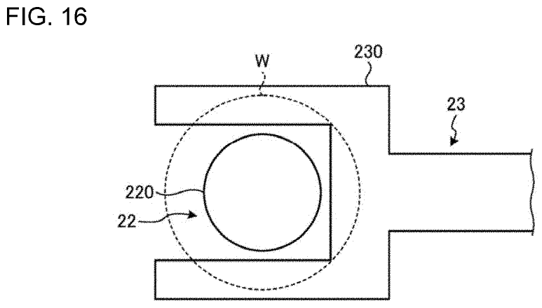

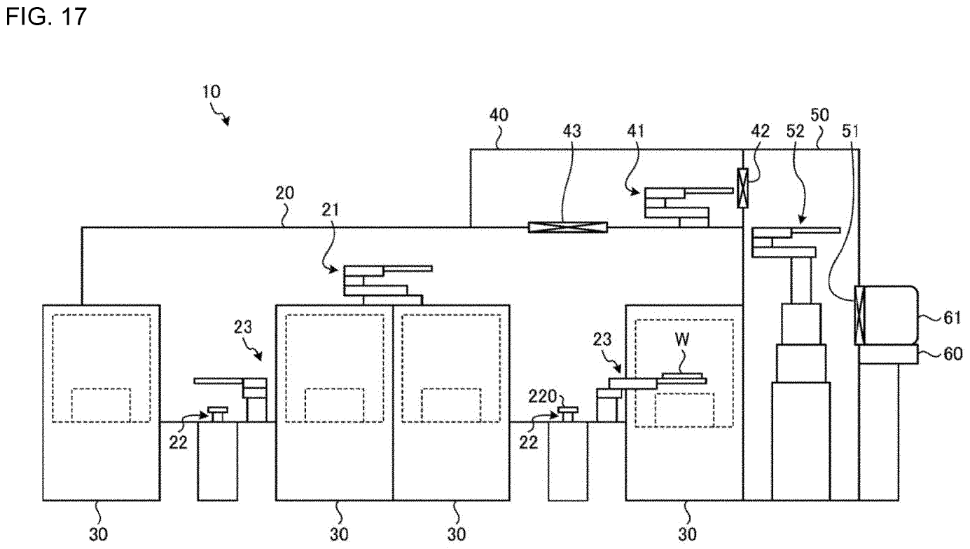

As the arm 221 in the transfer robot 22 retracts, the substrate W is transferred from the substrate support 220 in the transfer robot 22 to the substrate support 230 in the transfer robot 23 as shown in, for example, FIG. 15. The positional relationship between the substrate support 220 in the transfer robot 22 and the substrate support 230 in the transfer robot 23 is as shown in, for example, FIG. 16. The substrate support 220 in the transfer robot 22 and the substrate support 230 in the transfer robot 23 can transfer and receive the substrate W between them without interfering with each other. The gate valve 31 in the PM 30 is then opened, the substrate support 230 receiving the substrate W is placed into the PM 30, and the substrate W is loaded into the PM 30 as shown in, for example, FIG. 17.

When the substrate W is unloaded from the PM 30, the substrate W in the PM 30 is placed on the substrate support 230 in the transfer robot 23 and unloaded from the PM 30. The substrate W is transferred from the substrate support 230 in the transfer robot 23 to the substrate support 220 in the transfer robot 22, and the gate valve 43 is opened. As the arm 221 in the transfer robot 22 extends, the substrate support 220 receiving the substrate W is placed into the LLM 40. The substrate support 410 in the transfer robot 41 is then placed below the substrate support 220 in the transfer robot 22. As the arm 221 in the transfer robot 22 retracts, the substrate W is transferred from the substrate support 220 in the transfer robot 22 to the substrate support 410 in the transfer robot 41. The gate valve 43 is closed, and the pressure in the LLM 40 is then increased from a vacuum atmosphere to an ambient atmosphere. The gate valve 42 is then opened, the substrate support 520 in the transfer robot 52 is placed into the LLM 40, and the substrate W is transferred from the substrate support 410 in the transfer robot 41 to the substrate support 520 in the transfer robot 52. As the arm 521 in the transfer robot 52 retracts, the substrate support 520 receiving the substrate W is placed into the FOUP 61. The substrate W is thus stored into the FOUP 61.

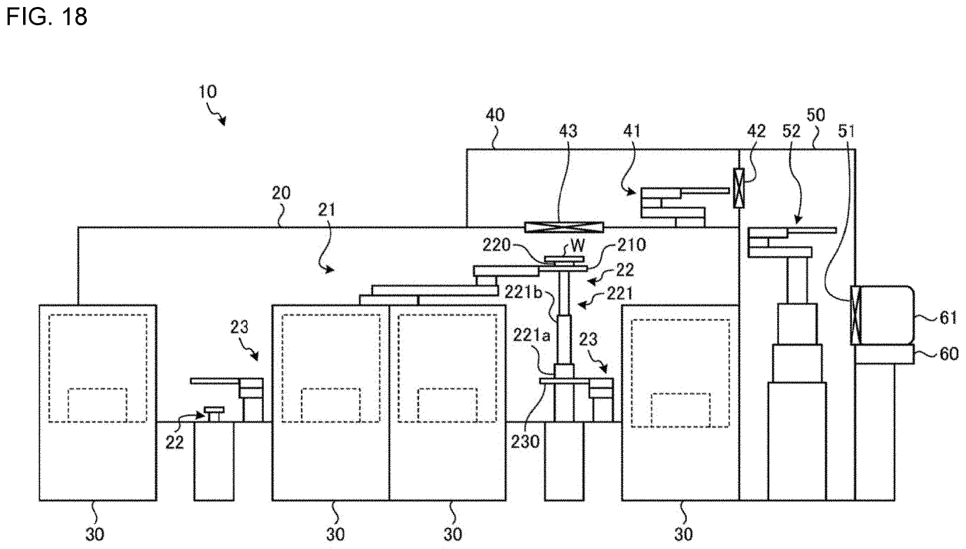

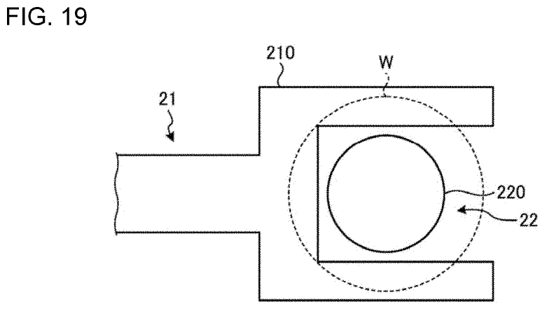

When a substrate W is loaded into another PM 30, the substrate W unloaded from the LLM 40 by the transfer robot 22 is transferred to the substrate support 210 in the transfer robot 21 as shown in, for example, FIG. 18. The positional relationship between the substrate support 220 in the transfer robot 22 and the substrate support 210 in the transfer robot 21 is as shown in, for example, FIG. 19. The substrate support 220 in the transfer robot 22 and the substrate support 210 in the transfer robot 21 can transfer and receive the substrate W between them without interfering with each other.

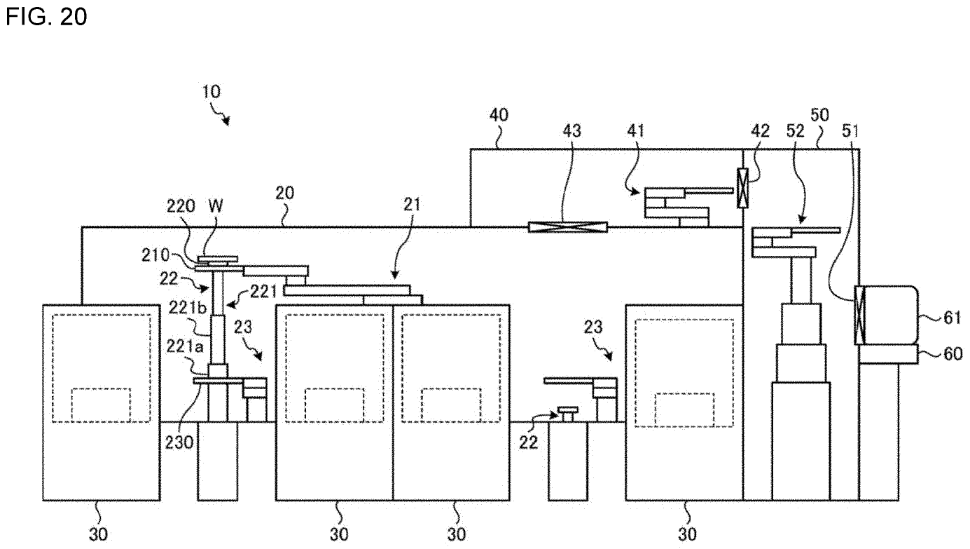

The transfer robot 21 then moves the substrate W to above the transfer robot 22 located near the other PM 30. As the arm 221 in the transfer robot 22 located near the other PM 30 extends, the substrate support 220 in the transfer robot 22 lifts the substrate W from the substrate support 210 in the transfer robot 21 as shown in, for example, FIG. 20. The substrate W is then transferred from the substrate support 210 in the transfer robot 21 to the substrate support 220 in the transfer robot 22. The substrate support 210 in the transfer robot 21 then retracts from below the substrate support 220 in the transfer robot 22.

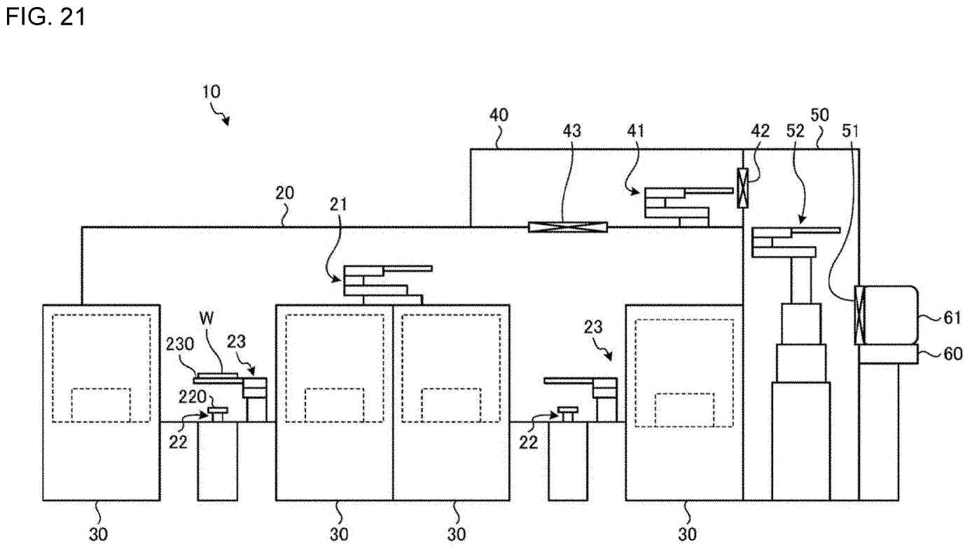

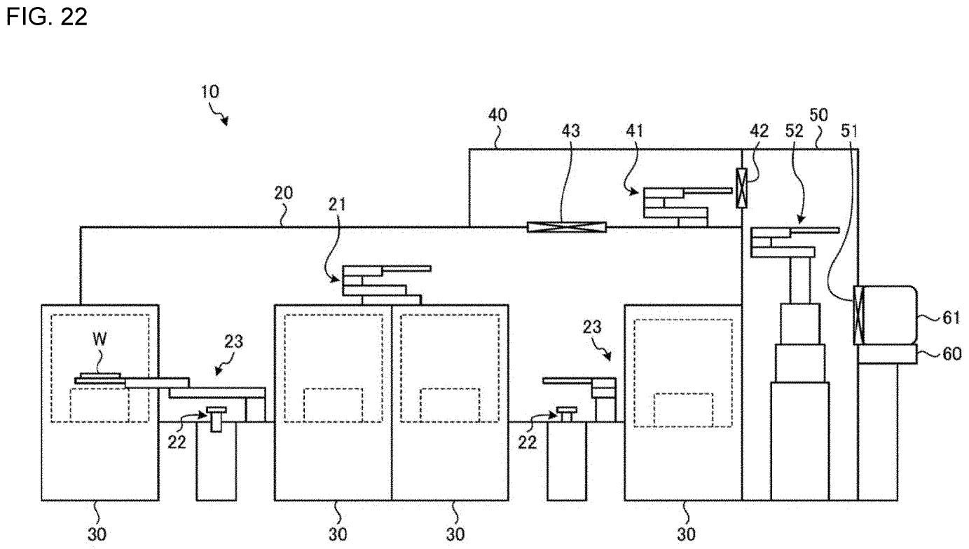

As the arm 221 in the transfer robot 22 retracts, the substrate W is then transferred from the substrate support 220 in the transfer robot 22 to the substrate support 230 in the transfer robot 23 as shown in, for example, FIG. 21. The gate valve 31 in the PM 30 is then opened, the substrate support 230 receiving the substrate W is placed into the PM 30, and the substrate W is loaded into the PM 30 as shown in, for example, FIG. 22.

A description of one embodiment is described as set forth above. As described above, the substrate processing system 10 according to the present embodiment includes one or more PMs 30 and the VTM 20. At least one PM 30 and the VTM 20 overlap with each other at least partially as viewed from above. This structure reduces the installation area of the substrate processing system 10.

An economic value from the substrate processing system 10 can be evaluated by an index (or metric) defined by, for example, a wafer price per space (WPPS). The WPPS is calculated using, for example, Formula 1 below.

WPPS=(WPD×operation rate×yield)/installation area×equipment price (1)

In Formula 1 above, the wafers per day (WPD) is the number of substrates W that can be processed per day.

The structure according to the present embodiment can reduce (as compared with conventional systems) the installation area in Formula 1 above, and can increase the value of the WPPS (as compared with conventional systems), and thus the overall economic value of the substrate processing system 10.

In the above embodiment, the VTM 20 is located on at least one PM 30, which is one characteristic that simplifies the structure of the substrate processing system 10.

In the above embodiment, the substrate processing system 10 further includes the LLM 40 connected to the VTM 20. At least one PM 30 and the LLM 40 overlap with each other at least partially as viewed from above. Consequently, this structure reduces the installation area of the substrate processing system 10.

In the above embodiment, at least a part of the VTM 20 is located between at least one PM 30 and the LLM 40. At least one PM 30, the VTM 20, and the LLM 40 overlap with one another at least partially as viewed from above. This structure reduces the installation area of the substrate processing system 10.

In the above embodiment, the LLM 40 is located on the VTM 20. This simplifies the structure of the substrate processing system 10.

In the above embodiment, the substrate processing system 10 includes the transfer robot 22 located in the VTM 20 to transfer and receive the substrate W between the VTM 20 and the PM 30. The transfer robot 22 includes the substrate support 220 on which the substrate W is placeable, and the arm 221 that moves the substrate support 220 in the vertical direction. The arm 221 includes the cylinder 221a with the axis in the vertical direction, and the cylinder 221b placeable in the cylinder 221a and coaxial with the cylinder 221a. The arm 221 is extendable along the axis of the cylinder 221a to move the substrate support 220 in the vertical direction by sliding the cylinder 221b relative to the cylinder 221a. This structure reduces the installation area of the transfer robot 22.

### Others Features and Characteristics

The techniques, structures, and arrangements according to the present disclosure are not limited to the embodiments described above, and may be changed variously within the scope of the present disclosure.

In the above embodiment, for example, the LLM 40 is located on the VTM 20, but the present disclosure is not limited to this approach. In other embodiments, the LLM 40 may be located adjacent to the VTM 20. In this case as well, at least one PM 30 and the VTM 20 overlap with each other at least partially as viewed from above. The substrate processing system 10 is installable in a smaller installation area than when the VTM 20, the PMs 30, the LLM 40, and the EFEM 50 are all arranged horizontally.

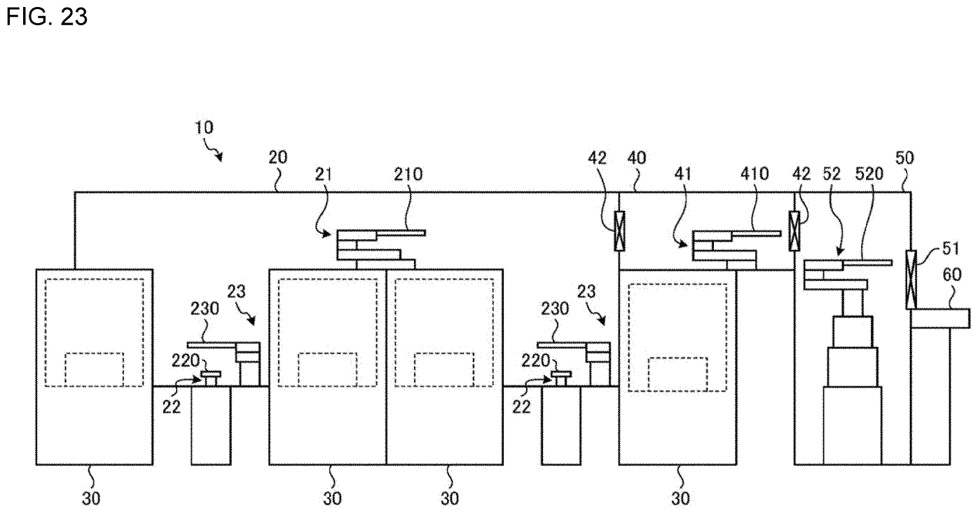

When the LLM 40 is located adjacent to the VTM 20 as well, the PMs 30 and the LLM 40 may overlap with each other at least partially as shown in, for example, FIG. 23. FIG. 23 is a schematic cross-sectional view of a substrate processing system 10 in another example. The substrate processing system 10 including the VTM 20, the PMs 30, and the LLM 40 in the illustrated arrangement is also installable in a smaller installation area.

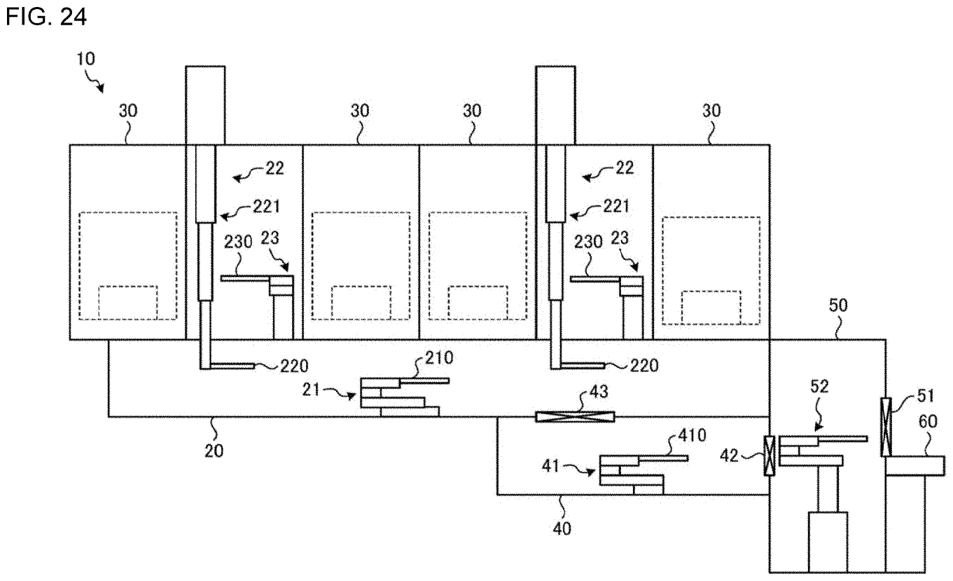

In the above embodiment, the VTM 20 is partially located on at least one PM 30, and the LLM 40 is located on the VTM 20, but the present disclosure is not limited to this approach. In other embodiments, as shown in, for example, FIG. 24, the VTM 20 may be located on the LLM 40, and at least one PM 30 may be located on a part of the VTM 20. FIG. 24 is a schematic cross-sectional view of a substrate processing system 10 in another example. In the example of FIG. 24, the arm 221 in the transfer robot 22 in the VTM 20 is extendable in the vertical direction from an upper portion of the VTM 20 to move the substrate support 220. The substrate processing system 10 according to the present embodiment is also installable in a smaller installation area.

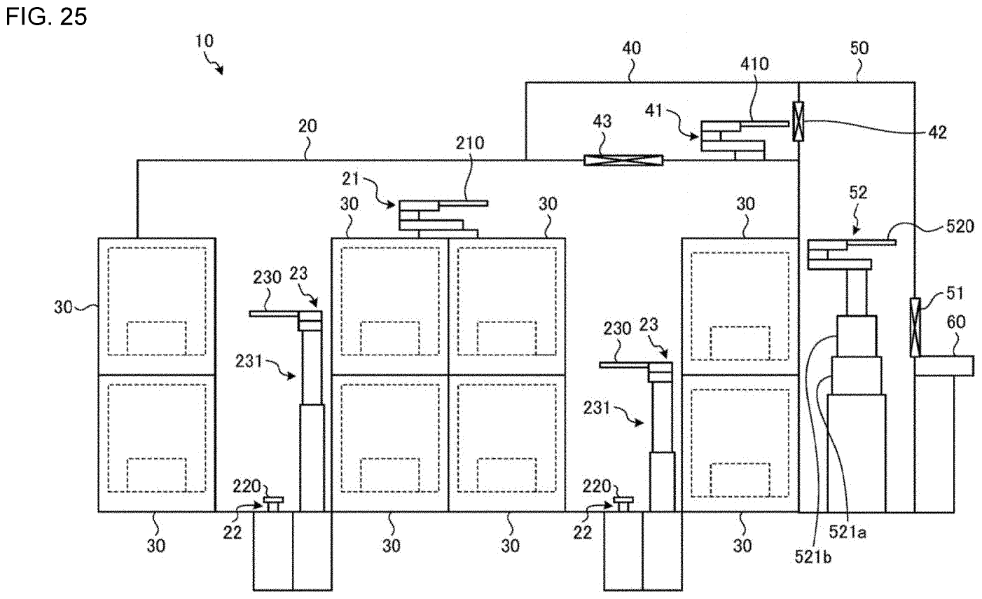

In the above embodiment, multiple PMs 30 are arranged horizontally, but the technique according to the present disclosure is not limited to this. In another embodiment shown in, for example, FIG. 25, multiple PMs 30 may be stacked in the vertical direction. FIG. 25 is a schematic cross-sectional view of a substrate processing system 10 in another example. In the example of FIG. 25, the multiple PMs 30 are stacked in the vertical direction in pairs. In the example of FIG. 25, the arm 231 in each transfer robot 23 is extendable in the vertical direction to load and unload a substrate W to and from the upper PM 30 and to load and unload a substrate W to and from the lower PM 30. The substrate processing system 10 including the multiple PMs 30 is thus installable in a smaller installation area as well. Although two PMs 30 are stacked in the vertical direction in the example of FIG. 25, more than two PMs 30 may be stacked in the vertical direction.

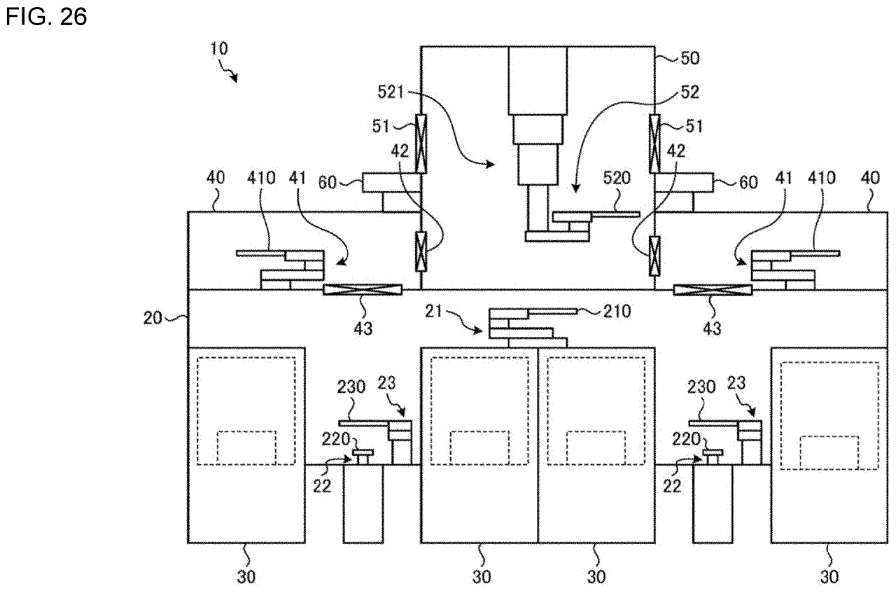

Although the EFEM 50 is located lateral to the VTM 20 in the above embodiment, the technique according to the present disclosure is not limited to this. In other embodiments, the EFEM 50 and the VTM 20 may overlap with each other at least partially as viewed from above. At least one LP 60 and the LLM 40 may overlap with each other at least partially as viewed from above. FIG. 26 is a schematic cross-sectional view of a substrate processing system 10 in another example. The substrate processing system 10 in the example of FIG. 26 includes the EFEM 50 located on the VTM 20 and multiple LPs 60 located on the LLM 40. In the example of FIG. 26, the arm 521 in the transfer robot 52 in the EFEM 50 is extendable in the vertical direction from an upper portion of the EFEM 50 to move the substrate support 520 in the vertical direction. The substrate processing system 10 according to the present embodiment is also installable in a smaller installation area.

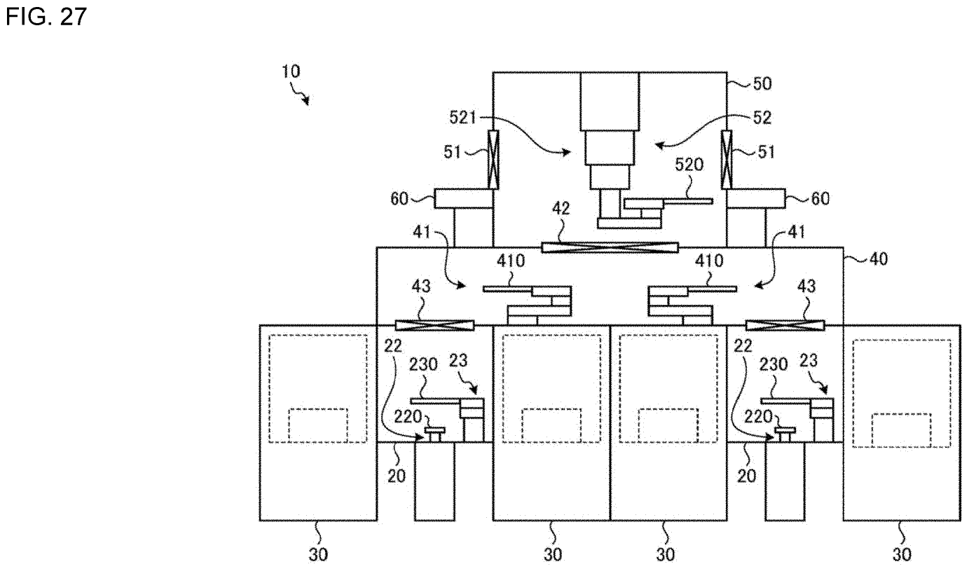

Although the substrate processing system 10 illustrated in FIG. 26 includes multiple LLMs 40 located lateral to the EFEM 50, the technique according to the present disclosure is not limited to this. In other embodiments, the LLM 40 may be located under the EFEM 50 as shown in, for example, FIG. 27. FIG. 27 is a schematic cross-sectional view of a substrate processing system 10 in another example. In the example of FIG. 27, the transfer robot 41 in the LLM 40 receives the substrate W and transfers the substrate W through the gate valve 43 to the substrate support 220 in the transfer robot 22. In the example of FIG. 27, the VTM 20 includes no transfer robot 21. Although the LLM 40 includes two transfer robots 41 in the example of FIG. 27, the LLM 40 may include a single transfer robot 41.

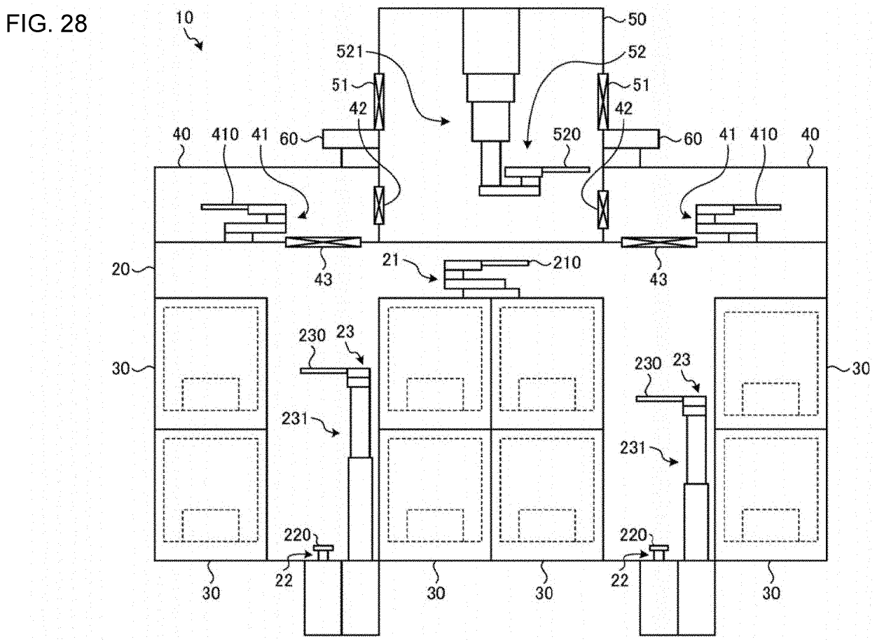

Although the substrate processing system 10 illustrated in FIG. 26 includes multiple PMs 30 arranged horizontally, the technique according to the present disclosure is not limited to this. In other embodiments, multiple PMs 30 may be stacked in the vertical direction as shown in, for example, FIG. 28. FIG. 28 is a schematic cross-sectional view of a substrate processing system 10 in another example. Although two PMs 30 stacked in the vertical direction in the example of FIG. 28, more than two PMs 30 may be stacked in the vertical direction. The substrate processing system 10 including the multiple PMs 30 is thus installable in a smaller installation area as well.

Although each PM 30 uses CCP for processing in the above embodiment as an example of a plasma source, the plasma source is not limited to this. Plasma sources other than CCP include, for example, inductively coupled plasma (ICP), microwave-excited surface wave plasma (SWP), electron cyclotron resonance plasma (ECP), and helicon wave excited plasma (HWP).

Each PM 30 in the above embodiment uses plasma to process the substrate W, but the technique according to the present disclosure is not limited to this. Each PM 30 that performs processing on the substrate W may be a device that performs non-plasma processing, such as heat treatment or chemical vapor deposition (CVD).

The embodiments disclosed herein are illustrative in all aspects and should not be construed to be restrictive. The above embodiments may be implemented in various forms. The components in the above embodiments may be eliminated, substituted, or modified in various forms without departing from the spirit and scope of the claims.

### REFERENCE SIGNS LIST

W Substrate
10 Substrate processing system
12 Control device
12a Computer
12a1 Processor
12a2 Storage
12a3 Communication interface
20 Vacuum transfer module (VTM)
21 Transfer robot
210 Substrate support
22 Transfer robot
220 Substrate support
221 Arm
221a Cylinder
221b Cylinder
23 Transfer robot
230 Substrate support
231 Arm
30 Process module (PM)
31 Gate valve
32 Opening
310 Plasma processing chamber
310a Side wall
310e Gas outlet
310s Plasma processing space
311 Substrate support
3111 Body
31110 Base
31111 Electrostatic chuck (ESC)
3112 Ring assembly
313 Shower head electrode
320 Gas supply unit
321 Gas source
322 Flow controller
330 Power supply
331 Radio frequency (RF) power supply
332 Direct current (DC) power supply
340 Exhaust system
40 Loadlock module (LLM)
41 Transfer robot
410 Substrate support
42 Gate valve
43 Gate valve
50 Equipment front end module (EFEM)
51 Gate valve
52 Transfer robot
520 Substrate support
521 Arm
521a Cylinder
521b Cylinder
60 Load port (LP)
61 Front opening unified pod (FOUP)

What is claimed is:

1. A substrate processing system, comprising:
one or more process modules configured to process a substrate therein; and
a vacuum transfer module configured to transfer the substrate within a vacuum atmosphere into the one or more process modules,
wherein at least one of the one or more process modules and the vacuum transfer module at least partially overlap with each other as viewed from above.

2. The substrate processing system according to claim 1, wherein
the vacuum transfer module is located over or under the at least one of the one or more process modules.

3. The substrate processing system according to claim 2, further comprising:
a loadlock module connected to the vacuum transfer module.

4. The substrate processing system according to claim 3, wherein
the at least one of the one or more process modules and the loadlock module at least partially overlap with each other as viewed from above.

5. The substrate processing system according to claim 3, wherein
at least a part of the vacuum transfer module is disposed between the at least one of the one or more process modules and the loadlock module, and
the at least one of the one or more process modules, the vacuum transfer module, and the loadlock module at least partially overlap with one another as viewed from above.

6. The substrate processing system according to claim 4, wherein
at least a part of the vacuum transfer module is disposed between the at least one of the one or more process modules and the loadlock module, and
the at least one of the one or more process modules, the vacuum transfer module, and the loadlock module at least partially overlap with one another as viewed from above.

7. The substrate processing system according to claim 3, wherein
the loadlock module is located over or under the vacuum transfer module.

8. The substrate processing system according to claim 6, wherein
the loadlock module is located over or under the vacuum transfer module.

9. The substrate processing system according to claim 3, further comprising:
an atmospheric transfer module connected to the loadlock module.

10. The substrate processing system according to claim 9, wherein
the atmospheric transfer module and the vacuum transfer module at least partially overlap with each other as viewed from above.

11. The substrate processing system according to claim 9, wherein
the atmospheric transfer module is located over or under the vacuum transfer module.

12. The substrate processing system according to claim 9, further comprising:
one or more load ports connected to the atmospheric transfer module.

13. The substrate processing system according to claim 11, further comprising:
one or more load ports connected to the atmospheric transfer module.

14. The substrate processing system according to claim 12, wherein
at least one of the one or more load ports and the loadlock module at least partially overlap with each other as viewed from above.

15. The substrate processing system according to claim 13, wherein
at least one of the one or more load ports and the loadlock module at least partially overlap with each other as viewed from above.

16. The substrate processing system according to claim 1, wherein
the one or more process modules include a plurality of process modules stacked in a vertical direction so as to at least partially overlap with each other as viewed from above.

17. The substrate processing system according to claim 15, wherein
the one or more process modules include a plurality of process modules stacked in a vertical direction so as to at least partially overlap with each other as viewed from above.

18. The substrate processing system according to claim 1, further comprising:
a transfer robot disposed in the vacuum transfer module to transfer the substrate between the vacuum transfer module and the one or more process modules,
wherein the transfer robot includes
a substrate support on which the substrate is placeable, and
an arm to move the substrate support in a vertical direction,
the arm includes
a first cylinder with an axis in the vertical direction, and
a second cylinder disposed in the first cylinder so as to be coaxial with the first cylinder, and
the arm is extendable along the axis of the first cylinder to move the substrate support in the vertical direction by sliding the second cylinder relative to the first cylinder.

19. The substrate processing system according to claim 3, further comprising:
a transfer robot disposed in the vacuum transfer module to transfer the substrate between the vacuum transfer module and the one or more process modules,
wherein the transfer robot includes
a substrate support on which the substrate is placeable, and
an arm to move the substrate support in a vertical direction,
the arm includes
a first cylinder with an axis in the vertical direction, and
a second cylinder disposed in the first cylinder so as to be coaxial with the first cylinder, and
the arm is extendable along the axis of the first cylinder to move the substrate support in the vertical direction by sliding the second cylinder relative to the first cylinder.

20. The substrate processing system according to claim 16, further comprising:
a transfer robot disposed in the vacuum transfer module to transfer the substrate between the vacuum transfer module and the one or more process modules,
wherein the transfer robot includes
a substrate support on which the substrate is placeable, and
an arm to move the substrate support in a vertical direction,
the arm includes
a first cylinder with an axis in the vertical direction, and
a second cylinder disposed in the first cylinder so as to be coaxial with the first cylinder, and
the arm is extendable along the axis of the first cylinder to move the substrate support in the vertical direction by sliding the second cylinder relative to the first cylinder.
